(19) United States
(12) Patent Application Publication
(10) Pub. No.: US 2025/0239318 A1
(43) Pub. Date: Jul. 24, 2025

(54) NONVOLATILE MEMORY DEVICE AND STORAGE DEVICE

(71) Applicant: Samsung Electronics Co., Ltd., Suwon-si (KR)

(72) Inventors: Jong Hoon PARK, Suwon-si (KR); JAE-DUK YU, Suwon-si (KR); SANG SOO PARK, Suwon-si (KR)

(21) Appl. No.: 18/950,486

(22) Filed: Nov. 18, 2024

(30) Foreign Application Priority Data
Jan. 23, 2024 (KR) 10-2024-0010020

(51) Int. Cl. G11C 29/12; G11C 29/46

(52) U.S. Cl. CPC G11C 29/1201; G11C 29/12015; G11C 29/46; G11C 2029/1202

(57) ABSTRACT

A nonvolatile memory device comprising a memory cell array including a first block including a first sub block having a first plurality of memory cells and a second sub block having a second plurality of memory cells, and a second block including a third plurality of memory cells and being a full block that is not divided into sub blocks. The nonvolatile memory device further comprising a control logic configured to write, read, and erase data to and from the memory cell array. The control logic further configured to perform a first test to detect a defect of the second block in response to a first erase command for the second block, and performs a second test different from the first test to detect a defect of the first sub block in response to a second erase command for the first sub block.

### CROSS-REFERENCE TO RELATED APPLICATION

This application claims priority from Korean Patent Application No. 10-2024-0010020 filed on Jan. 23, 2024 in the Korean Intellectual Property Office and all the benefits accruing therefrom under 35 U.S.C. 119, the content of which in its entirety is herein incorporated by reference.

### BACKGROUND

### Technical Field

The present disclosure relates to a nonvolatile memory device and a storage device.

### Description of the Related Art

In a nonvolatile memory device such as a NAND flash memory, due to characteristics of the memory device, it may be necessary to erase data written in a memory cell before writing data to that memory cell.

In a nonvolatile memory device, data is erased in units of blocks instead of being erased in just one specific memory cell due to characteristics of the device. In other words, a block may correspond to a minimum unit for erasing data in a nonvolatile memory device.

With the development of technology, the number of stages of the nonvolatile memory device such as a NAND flash memory is gradually increasing. In view of a structure of the device, as the number of stages is increased, a size of a block may be increased, and accordingly, a size of a minimum unit capable of erasing data may be increased, whereby inefficiency of an erase operation may be also increased.

Therefore, the block may be divided into several sub blocks so that data may be erased in units of sub blocks, whereby the efficiency of the erase operation may be increased.

In the nonvolatile memory device, a channel hole burst defect may occur due to a progressive defect, and it may be necessary to retain valid data from the progressive defect by transferring the valid data in the block.

### BRIEF SUMMARY

An object of the present disclosure is to provide a nonvolatile memory device in which reliability is increased by retaining data from a progressive defect.

Another object of the present disclosure is to provide a storage device in which reliability is increased by retaining data from a progressive defect.

The objects of the present disclosure are not limited to those mentioned above and additional objects of the present disclosure, which are not mentioned herein, will be clearly understood by those skilled in the art from the following description of the present disclosure.

According to an aspect of the present disclosure, there is provided a nonvolatile

memory device comprising a memory cell array including a first including a first sub block having a first plurality of memory cells and a second sub block having a second plurality of memory cells, and a second block including a third plurality of memory cells and being a full block that is not divided into sub blocks, a control logic configured to write, read, and erase data to and from the memory cell array, a voltage generator configured to generate voltage applied to the memory cell array, a row decoder configured to select wordlines connected to the first plurality of memory cells, the second plurality of memory cells and the third plurality of memory cells and a page buffer configured to select and sense bitlines connected to the first plurality of memory cells, the second plurality of memory cells and the third plurality of memory cells, wherein the control logic performs a first test to detect a defect of the second block in response to a first erase command for the second block, and performs a second test different from the first test to detect a defect of the first sub block in response to a second erase command for the first sub block.

According to other aspect of the present disclosure, there is provided a nonvolatile memory device comprises a memory cell array including a first block including a first sub block having a first plurality of memory cells and a second sub block having a second plurality of memory cells, and a second block including a third plurality of memory cells, a control logic configured to write, read, and erase data to and from the memory cell array, a voltage generator configured to generate voltage applied to the memory cell array, a row decoder configured to select wordlines connected to the first plurality of memory cells, the second plurality of memory cells and the third plurality of memory cells and a page buffer configured to select and sense bitlines connected to the first plurality of memory cells, the second plurality of memory cells and the third plurality of memory cells, wherein the control logic performs a first test to detect a defect of the first sub block in response to a first erase command for the first sub block, transfers data of the second sub block to the second block when the defect of the first sub block is detected, and switches the first block into a third block which is a full block which is not divided into sub blocks.

According to an aspect of the present disclosure, there is provided a storage device comprises a nonvolatile memory device and a storage controller controlling an operation of the nonvolatile memory device, wherein the nonvolatile memory device includes a memory cell array including a first block including a first sub block including a first plurality of memory cells and a second sub block including a second plurality of memory cells, and a second block including a third plurality of memory cells and being a full block that is not divided into sub blocks, a control logic configured to write, read, and erase data to and from the memory cell array by receiving a command of the storage controller, a voltage generator configured to generate voltage applied to the memory cell array, a row decoder configured to select wordlines connected to the first plurality of memory cells, the second plurality of memory cells and the third plurality of memory cells and a page buffer configured to select and sense bitlines connected to the first plurality of memory cells, the second plurality of memory cells and the third plurality of memory cells, and the storage controller controls the control logic to perform a first test for detecting a defect of the first sub block in order to erase data of the first sub block, and controls the control logic to perform a second test, which detects a defect of the second block and is different from the first test, in order to erase data of the second block.

It should be noted that the effects of the present disclosure are not limited to those described above, and other effects of the present disclosure will be apparent from the following description.

### BRIEF DESCRIPTION OF THE DRAWINGS

FIG. 1 is an exemplary block diagram illustrating a host-storage system including a storage device according to some embodiments.

FIG. 2 is an exemplary block diagram illustrating a nonvolatile memory device according to some embodiments.

FIG. 3 is an exemplary perspective view illustrating a memory block included in a memory cell array.

FIG. 4 is an example block diagram illustrating a memory cell array.

FIG. 5 is an example circuit diagram illustrating a memory block included in a memory cell array.

FIG. 6 is an example circuit diagram illustrating a memory block included in a memory cell array.

FIG. 7 is an exemplary flow chart illustrating an erase process of a full block.

FIG. 8 is an exemplary block diagram illustrating an erase process of a full block.

FIG. 9 is an exemplary flow chart illustrating an erase process of a sub block.

FIG. 10 is an exemplary block diagram illustrating an erase process of a sub block.

FIG. 11 is an exemplary flow chart illustrating an erase process of a sub block.

FIG. 12 is an exemplary block diagram illustrating an erase process of a sub block.

FIG. 13 is an exemplary block diagram illustrating a nonvolatile memory device according to some embodiments.

FIG. 14 is an exemplary view illustrating a defect test process of a full block.

FIG. 15 is an exemplary view illustrating a defect test process of a sub block.

FIG. 16 is an exemplary graph illustrating comparison between conditions of a first test and a second test.

FIG. 17 is an exemplary graph illustrating comparison between conditions of a first test and a second test.

FIG. 18 is an exemplary block diagram illustrating a nonvolatile memory device according to some embodiments.

FIG. 19 is an exemplary view illustrating a defect test process of a full block.

FIG. 20 is an exemplary view illustrating a defect test process of a sub block.

FIG. 21 is an exemplary graph illustrating comparison between conditions of a first test and a second test.

FIG. 22 is an exemplary graph illustrating comparison between conditions of a first test and a second test.

FIG. 23 is an exemplary dispersion graph illustrating comparison between conditions of a first test and a second test.

### DETAILED DESCRIPTION OF THE DISCLOSURE

Hereinafter, embodiments according to the technical spirits of the present disclosure will be described with reference to the accompanying drawings.

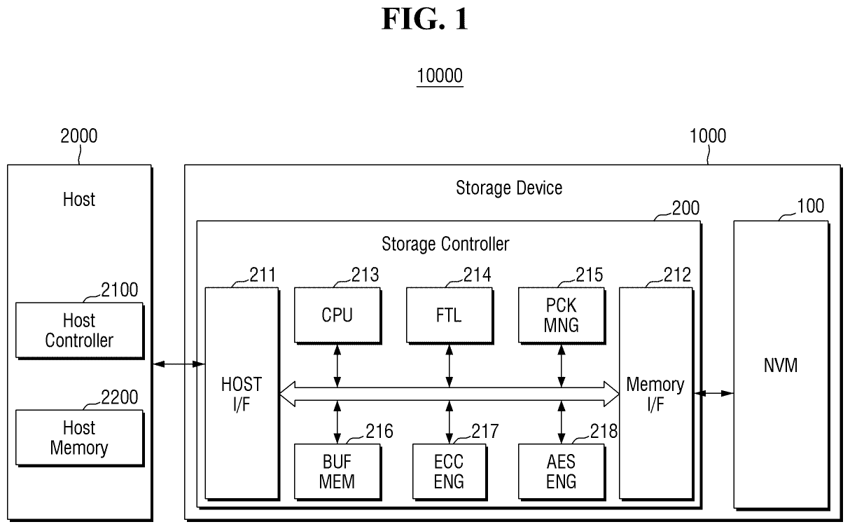

FIG. 1 is an exemplary block diagram illustrating a host-storage system including a storage device according to some embodiments.

Referring to FIG. 1, a host-storage system 10000 may include a host 2000 and a storage device 1000. The storage device 1000 may include a storage controller 200 and a nonvolatile memory (NVM) device 100. The host 2000 may include a host controller 2100 and a host memory 2200. The host memory 2200 may serve as a buffer memory for temporarily storing data to be transmitted to the storage device 1000 or data transmitted from the storage device 1000.

The storage device 1000 may include storage media for storing data in response to a request from the host 2000. As an example, the storage device 1000 may include at least one of a solid state drive (SSD), an embedded memory or a detachable external memory. When the storage device 1000 is an SSD, the storage device 1000 may be a device that complies with a non-volatile memory express (NVMe) standard. When the storage device 1000 is the embedded memory or the external memory, the storage device 1000 may be a device that complies with a universal flash storage (UFS) standard or an embedded multi-media card (eMMC) standard. Each of the host device 2000 and the storage device 1000 may generate and transmit packets according to a standard protocol that is employed.

When the nonvolatile memory 100 of the storage device 1000 includes a flash memory, the flash memory may include a 2D NAND memory array or a 3D (or vertical) NAND (VNAND) memory array. As another example, the storage device 200 may include other various types of nonvolatile memories. For example, a magnetic random access memory (MRAM), a spin-transfer torque MRAM, a Conductive Bridging RAM (CBRAM), a Ferroelectric RAM (FeRAM), a Phase RAM (PRAM), a Resistive RAM and other various types of memories may be applied to the storage device 200.

The host controller 2100 and the host memory 2200 may be implemented as separate semiconductor chips. Also, the host controller 2100 and the host memory 2200 may be integrated into the same semiconductor chip. As an example, the host controller 2100 may be any one of a plurality of modules provided in an application processor, and the application processor may be implemented as a system on chip (SoC). In addition, the host memory 2200 may be an embedded memory provided in the application processor, or a nonvolatile memory or a memory module disposed outside the application processor.

The host controller 2100 may store data (e.g., write data) of a buffer region in the nonvolatile memory 100, or may manage an operation of storing data (e.g., read data) of the nonvolatile memory 100 in the buffer region.

The storage controller 200 may include a host interface 211, a storage memory interface 212, and a central processing unit (CPU) 213. In addition, the storage controller 200 may further include a flash translation layer (FTL) 214, a packet manager (PCK MNG) 215, a buffer memory (BUF MEM) 216, an error correction code engine (ECC ENG) 217, and an advanced encryption standard engine (AES ENG) 218. The storage controller 200 may further include a working memory (not shown) in which the flash translation layer (FTL) 214 is loaded, and a data write and read operation for the nonvolatile memory 100 may be controlled by execution of the flash translation layer by the CPU 213.

In detail, the storage device 1000 may receive a storage device driving signal from the host 2000 through the host interface 211. The CPU 213 may transmit an initialization command in response to the storage device driving signal. The initialization command may be transmitted to the nonvolatile memory device 100 through the storage memory interface 212.

The host interface 211 may transmit and receive packets to and from the host 2000. The packets transmitted from the host 2000 to the host interface 211 may include a command or data to be written in the nonvolatile memory device 100, and the packets transmitted from the host interface 211 to the host 2000 may include a response to the command or data read from the nonvolatile memory device 100. The storage memory interface 212 may transmit data to be written in the nonvolatile memory device 100 to the nonvolatile memory device 100 or receive data read from the nonvolatile memory device 100. The storage memory interface 212 may be implemented to comply with a standard regulation such as toggle or Open NAND Flash Interface (ONFI).

The flash translation layer 214 may perform various functions such as address mapping, wear-leveling and garbage collection. The address mapping operation is an operation of changing a logical address received from the host 2000 to a physical address used to actually store data in the nonvolatile memory 100. The wear-leveling is a technique for allowing blocks in the nonvolatile memory device 100 to be uniformly used to prevent a specific block from being excessively degraded, and may be implemented through firmware technology for balancing erase counts of physical blocks by way of example. The garbage collection is a technique for making sure of available capacity in the nonvolatile memory device 100 through a method of copying valid data of a block to a new block and then erasing the existing block.

The packet manager 215 may generate packets according to a protocol of an interface negotiated with the host 2000 or parse various kinds of information from the packets received from the host 2000. Also, the buffer memory 216 may temporarily store data to be written in the nonvolatile memory device 100 or data to be read from the nonvolatile memory 100.

The buffer memory 216 may be provided in the storage controller 200, but may be disposed outside the storage controller 200.

The ECC engine 217 may perform error detection and correction functions for the read data read from the nonvolatile memory device 100. In more detail, the ECC engine 217 may generate parity bits for write data to be written in the nonvolatile memory device 100, and the generated parity bits may be stored in the nonvolatile memory device 100 together with the write data. When reading the data from the nonvolatile memory device 100, the ECC engine 217 may correct an error of the read data by using the parity bits read from the nonvolatile memory device 100 together with the read data, and then may output the error-corrected read data.

The AES engine 218 may perform at least one of an encryption operation or a decryption operation for the data input to the storage controller 200 by using a symmetric-key algorithm.

According to some embodiments, the storage controller 200 may receive an erase command for a logical address from the host 2000 and transmit an erase command for a physical address of the corresponding nonvolatile memory device 100, generated by the flash translation layer 214, to the nonvolatile memory device 100 via the storage memory interface 212. The erase command for the physical address of the corresponding nonvolatile memory device 100 may include a defect test command for the corresponding physical address. The storage controller 200 may check whether the physical address of the nonvolatile memory device 100, which is to be erased, is in a full block or a sub block. The full block and the sub block will be described later. The storage controller 200 may set a condition of a defect test in accordance with the checked result and transmit a corresponding defect test command.

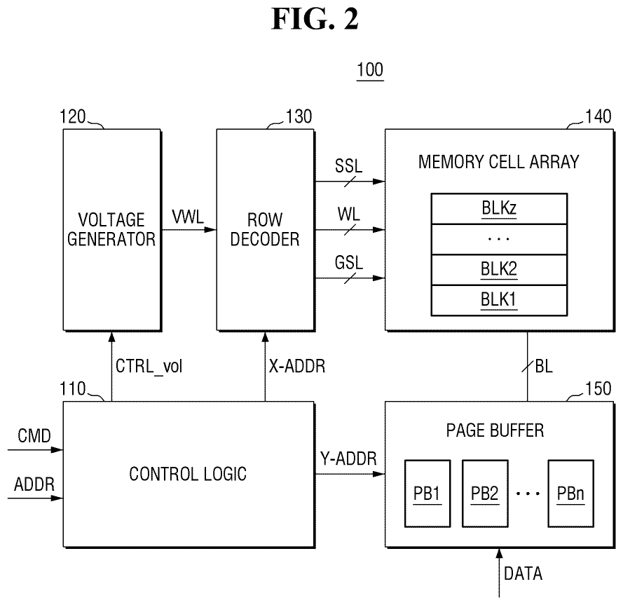

FIG. 2 is an exemplary block diagram illustrating a nonvolatile memory device according to some embodiments.

Referring to FIG. 2, the nonvolatile memory device 100 may include a control logic 110, a voltage generator 120, a row decoder 130, a memory cell array 140, and a page buffer 150. Although not shown in FIG. 2, the nonvolatile memory device 100 may further include a memory interface, and may further include a column logic, a pre-decoder, a temperature sensor, a command decoder, an address decoder, and the like.

The control logic 110 may control various operations in the nonvolatile memory device 100. The control logic 110 may output various control signals in response to a command CMD and/or an address ADDR from the memory interface. For example, the control logic 110 may output a voltage control signal CTRL_vol, a row address X-ADDR and a column address Y-ADDR.

The voltage generator 120 may generate various types of voltages for performing write, read and erase operations based on the voltage control signal CTRL_vol. For example, the voltage generator 120 may generate a write voltage, a read voltage, a write verification voltage, an erase voltage and the like as wordline voltages VWL.

The row decoder 130 may select one of the plurality of wordlines WL in response to the row address X-ADDR, and may select one of a plurality of string select lines SSL. For example, the row decoder 360 may apply the write voltage and the write verification voltage to the selected wordline during the write operation, may apply the read voltage to the selected wordline during the read operation, and may apply the erase voltage to the selected wordline during the erase operation.

The memory cell array 140 may include a plurality of memory blocks BLK1 to BLKz (z is a positive integer), each of which may include a plurality of memory cells. In the present disclosure, a ‘memory block’ may be simply referred to as a ‘block’ and hereinafter, a ‘memory block’ and a ‘block’ will be interchangeably used. The memory cell array 140 may be connected to the page buffer 150 through bitlines BL, and may be connected to the row decoder 130 through wordlines WL, string select lines SSL and ground select lines GSL.

The memory cell array 140 may include a three-dimensional memory cell array, and the three-dimensional memory cell array may include a plurality of NAND strings. Each NAND string may include memory cells respectively connected to wordlines vertically stacked on a substrate. The memory cell array 140 may also include a two-dimensional memory cell array, and the two-dimensional memory cell array may include the plurality of NAND strings disposed along row and column directions.

The page buffer 150 may include a plurality of page buffers PB1 to PBn (n is an integer greater than or equal to 2), wherein the plurality of page buffers PB1 to PBn may be respectively connected with the memory cells through the plurality of bitlines BL. The page buffer 150 may select at least one of the bitlines BL in response to the column address Y-ADDR. The page buffer 150 may operate as a write driver or a sense amplifier in accordance with an operation mode. For example, during a write operation, the page buffer 150 may apply a bitline voltage corresponding to data, which will be written, to the selected bitline. During a read operation, the page buffer 150 may sense data stored in the memory cell by sensing a current or voltage of the selected bitline.

According to some embodiments, the control logic 110 may receive an erase command from the storage controller 200 through a memory interface and control the voltage generator 120, the row decoder 130 and the page buffer 150 to erase data recorded in a memory block, which includes data to be erased, among the plurality of memory blocks BLK1 to BLKz. The control logic 110 may receive, from the storage controller 200, a defect test execution command for a memory block, which includes data to be erased, among the plurality of memory blocks BLK1 to BLKz through the memory interface.

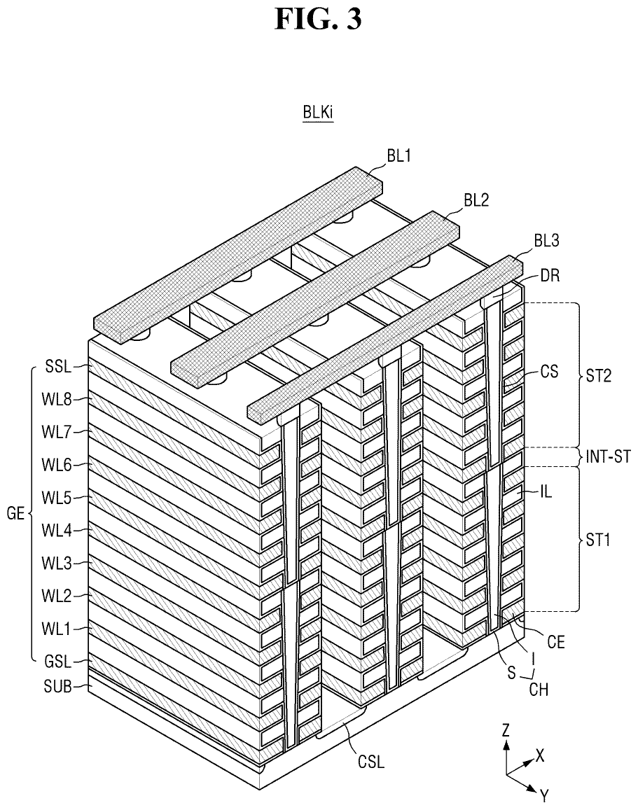

FIG. 3 is an exemplary perspective view illustrating a memory block included in a memory cell array.

Referring to FIG. 3, the memory block BLKi is formed in a vertical direction (direction Z) with respect to a substrate SUB. The substrate SUB may have a first conductivity type (e.g., p-type), and a common source line CSL doped with impurities of a second conductivity type (e.g., n-type) may be formed in the substrate SUB. A plurality of insulating materials IL elongated along a second direction (direction Y) may be sequentially provided in the vertical direction (direction Z) on a region of the substrate SUB between the common source lines CSL. For example, the plurality of insulating materials IL may be formed to be spaced apart from each other along a first direction (direction X). For example, the insulating materials IL may include an insulating material such as silicon oxide.

Channel structures CH sequentially disposed along the second direction (direction Y), passing through the insulating materials IL along the vertical direction (direction Z) are formed above the substrate SUB between the common source lines CSL. For example, the channel structures CH may be connected to the substrate SUB by passing through insulating materials

IL. For example, each channel structure CH may be composed of a plurality of materials. A surface layer S of the channel structure CH may include a silicon material having a first conductivity type, and may serve as a channel region. The channel structure CH may be referred to as a vertical channel structure or a pillar. An inner layer I of each channel structure CH may include an insulating material, such as silicon oxide, or an air gap.

A charge storage layer CS may be provided along exposed surfaces of the insulating layers IL, the channel structure CH and the substrate SUB. The charge storage layer CS may include a gate insulating layer (or referred to as ‘a tunneling insulating layer’), a charge trap layer and a blocking insulating layer. For example, the charge storage layer CS may have an oxide-nitride-oxide (ONO) structure. A gate electrode GE such as a ground select line GSL, a string select line SSL and wordlines WL1 to WL8 may be provided on the exposed surface of the charge storage layer CS. Drain contacts or drains DR are provided on the plurality of channel structures CH, respectively. For example, the drains DR may include a silicon material doped with impurities having a second conductivity type. Bitlines BL1 to BL3 elongated in the first direction (direction X) and spaced apart from one another as much as a specific distance along the second direction (direction Y) may be provided on the drains DR.

The memory block BLKi may include a first memory stack ST1 and a second memory stack ST2, which are stacked in the vertical direction (direction Z). For example, the wordlines WL1 to WL4 may be included in the first memory stack ST1, and the wordlines WL5 to WL8 may be included in the second memory stack ST2. An inter-stack region INT-ST may exist between the first memory stack ST1 and the second memory stack ST2 to ensure structural stability of the nonvolatile memory device (100 of FIG. 2) in a manufacturing process of the nonvolatile memory device (100 of FIG. 2). Two memory stacks are shown in FIG. 3, but are not limited thereto, and two or more memory stacks may be stacked in accordance with the manufacturing process.

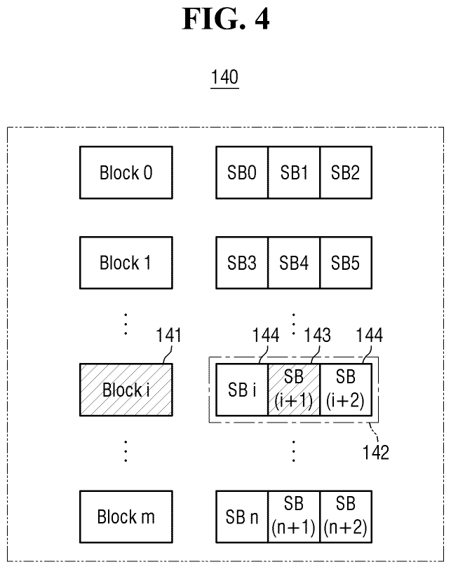

FIG. 4 is an example block diagram illustrating a memory cell array.

Referring to FIG. 4, the memory cell array 140 may include a plurality of memory blocks (or a plurality of blocks).

According to some embodiments, a block may be an erasable minimum memory unit. In a three-dimensional nonvolatile memory device in which wordlines are vertically stacked on a substrate, the block may be defined as a group of NAND strings that share all stacked wordlines. A sub block corresponds to a detailed memory unit obtained by dividing one block by a wordline unit or a select line unit. For example, the sub block may be defined as a unit of memory cells that share some wordlines among blocks.

The plurality of blocks included in the memory cell array 140 may include blocks divided into sub blocks and blocks that are not divided into sub blocks. The blocks that are not divided into sub blocks may be referred to as full blocks. When the blocks divided into sub blocks are erased, the blocks may be erased in units of sub blocks. In other words, for the blocks divided into sub blocks, the sub block may be an erasable minimum memory unit. For a full block, the full block may be an erasable minimum memory unit. For example, when the nonvolatile memory device (100 of FIG. 2) receives an erase command for a first block 141, which is a full block, an erase operation for all memory cells included in the first block 141 may be performed. For example, when the nonvolatile memory device receives an erase command for a first sub block 143 included in a second block 142, which is a block divided into sub blocks, an erase operation for all memory cells included in the second block 142 is not performed. Instead, an erase operation for all memory cells included in only the first sub block 143 may be performed. That is, an erase operation for memory cells included in the second sub block 144 may not be performed. The sub block, which is included in one block divided into a plurality of sub blocks and is not an object to be erased, may be referred to as a sister sub block of the sub block to be erased. Using this specific erase operation as an example, the second sub block 144 may be referred to as a sister sub block of the first sub block 143.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

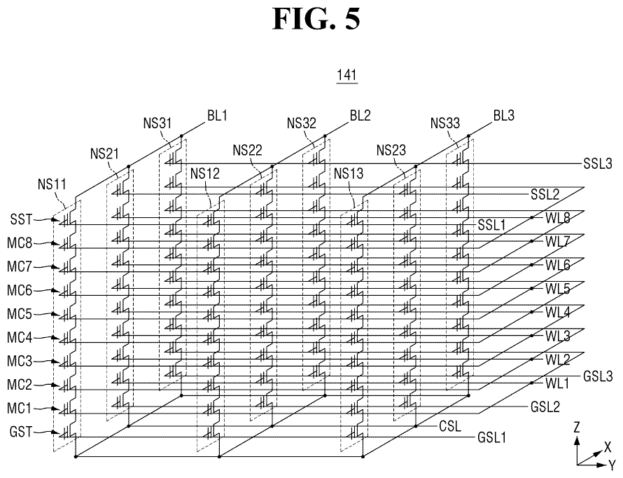

FIG. 5 is an example circuit diagram illustrating a memory block included in a memory cell array.

Referring to FIG. 5, the shown first block 141 represents a three-dimensional memory block formed on a substrate in a three-dimensional structure. The first block 141 may be a full block. For example, the plurality of NAND strings included in the first block 141 may be formed in a direction perpendicular to the substrate. The first block 141 may include a plurality of NAND strings NS11 to NS33 connected between the bitlines BL1 to BL3 and the common source line CSL. Each of the plurality of NAND strings NS11 to NS33 may include a string select transistor SST, a plurality of memory cells MC1 to MC8 and a ground select transistor GST. In FIG. 5, each of the plurality of NAND strings NS11 to NS33 includes eight memory cells MC1 to MC8, but is not limited thereto.

The string select transistor SST may be connected to corresponding string select line SSL1 to SSL3. The plurality of memory cells MC1 to MC8 may be connected to corresponding wordlines WL1 to WL8, respectively. A portion of the wordlines WL1 to WL8 may correspond to a dummy wordline. The ground select transistor GST may be connected to the corresponding ground select lines GSL1 to GSL3. The string select transistor SST may be connected to the corresponding bitline BL1 to BL3, and the ground select transistor GST may be connected to the common source line CSL.

Memory cells of the same height are commonly connected to one wordline (for example, WL1), and the ground select lines GSL1, GSL2 and GSL3 and the string select lines SSL1, SSL2 and SSL3 may be separated from each other. In FIG. 5, the first block 141 is connected to eight wordlines WL1 to WL8 and three bitlines BL1 to BL3, but is not limited thereto.

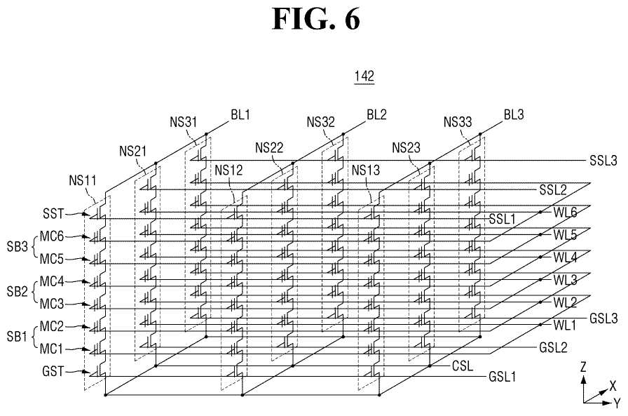

FIG. 6 is an example circuit diagram illustrating a memory block included in a memory cell array.

Referring to FIG. 6, the shown second block 142 represents a three-dimensional memory block formed on a substrate in a three-dimensional structure. Unlike the first block 141 of FIG. 5, the second block 142 may be a memory block divided into a plurality of sub blocks. The second block 142 may include a plurality of NAND strings NS11 to NS33 connected between the bitlines BL1 to BL3 and the common source line CSL. Each of the plurality of NAND strings NS11 to NS33 may include a string select transistor SST, a plurality of memory cells MC1 to MC6 and a ground select transistor GST. Although FIG. 6 shows that each of the plurality of NAND strings NS11 to NS33 includes six memory cells MC1 to MC6, but the present disclosure is not limited thereto.

The string select transistor SST may be connected to a corresponding one of the string select lines SSL1 to SSL3. The plurality of memory cells MC1 to MC6 may be connected to corresponding wordlines WL1 to WL6, respectively. A portion of the wordlines WL1 to WL6 may correspond to a dummy wordline. The ground select transistor GST may be connected to a corresponding one of the ground select lines GSL1 to GSL3. The string select transistor SST may be connected to a corresponding one of the bitlines BL1 to BL3, and the ground select transistor GST may be connected to the common source line CSL.

Memory cells of the same height are commonly connected to one wordline (for example, WL1), and the ground select lines GSL1, GSL2 and GSL3 and the string select lines SSL1, SSL2 and SSL3 may be separated from each other. In FIG. 6, the second block 142 is connected to six wordlines WL1 to WL6 and three bitlines BL1 to BL3, but is not limited thereto.

According to some embodiments, the second block 142 may be divided into a plurality of sub blocks. Each sub block may be divided in a direction of a wordline, may be divided based on the bitline BL or the string select line SSL, and may be divided in various ways. In the present disclosure, a sub-block is divided in a direction (Z direction) in which the memory cells are vertically stacked on a substrate. For example, the sub block SB1 may include memory cells, which are connected to the wordlines WL1 and WL2, among the memory cells included in the second block 142. The sub block SB2 may include memory cells, which are connected to the wordlines WL3 and WL4, among the memory cells included in the second block 142. The sub block SB3 may include memory cells, which are connected to the wordlines WL5 and WL6, among the memory cells included in the second block 142. When the sub block is divided in a direction in which the memory cells are vertically stacked on the substrate, the sub block may be divided based on the number of wordlines (or the number of memory cells) or may be divided based on the memory stack shown in FIG. 3, but is not limited thereto. Although FIG. 6 shows that the second block 142 is divided into three sub blocks, the present disclosure is not limited thereto.

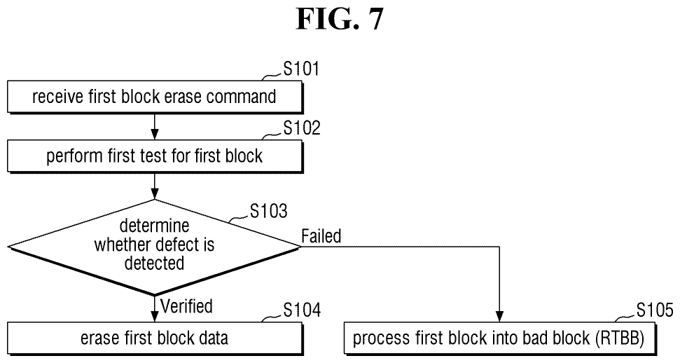

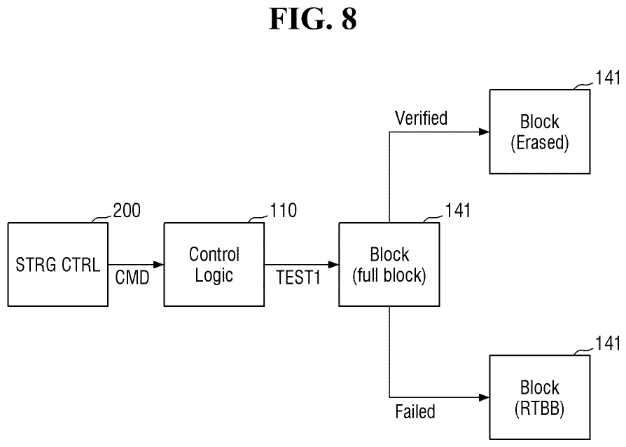

FIG. 7 is an exemplary flow chart illustrating an erase process of a full block. FIG. 8 is an exemplary block diagram illustrating an erase process of a full block.

Referring to FIGS. 7 and 8, the control logic 110 may receive an erase command of the first block 141 from the storage controller 200 (S101). The erase command of the first block 141 may include a defect test execution command for the first block 141. The first block 141 may be a full block. The control logic 110 may control the first block 141 to perform a first test TEST1 in order to determine whether the first block 141 is defective (S102). The control logic 110 may determine whether the first block 141 is defective in accordance with the result of the first test TEST1 after the first block 141 performs the first test TEST1 (S103). When it is determined that the first block 141 is not defective (when it is determined that the block has been verified) (S103—Verified), the control logic 110 may control the first block 141 to perform an erase operation of the data written in the first block 141 (S104). When it is determined that the first block 141 is defective (S103—Failed), the control logic 110 may switch the first block 141 to a run-time bad block (RTBB) (S105). When the first block 141 is switched to the run-time bad block, data may not be stored in the first block 141 anymore.

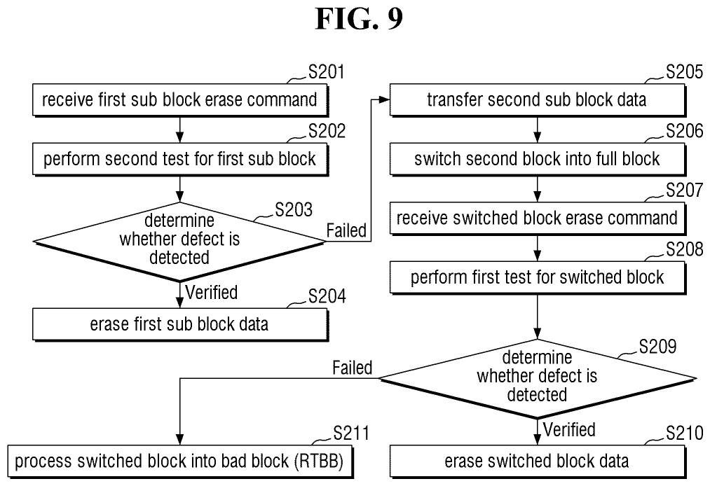

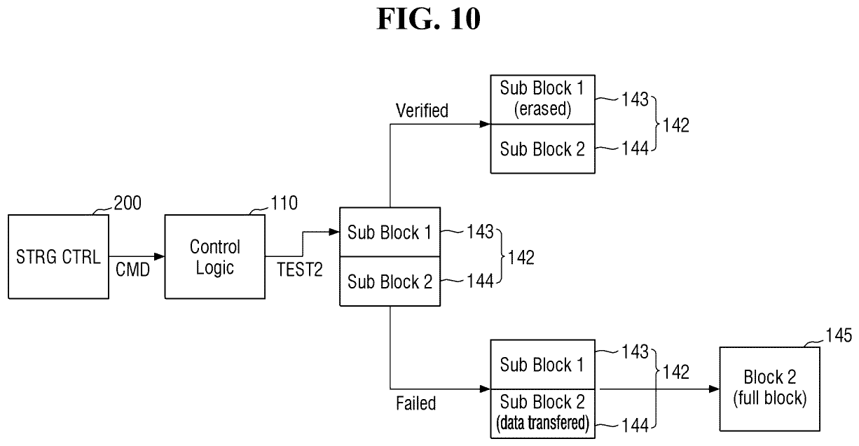

FIG. 9 is an exemplary flow chart illustrating an erase process of a sub block. FIG. 10 is an exemplary block diagram illustrating an erase process of a sub block.

Referring to FIGS. 9 and 10, unlike the first block (141 of FIG. 8), the second block 142 may be divided into a plurality of sub blocks. The second block 142 may include a first sub block 143 and a second sub block 144. In FIG. 10, the second block 142 is divided into two sub blocks, but this is only exemplary. The control logic 110 may receive an erase command of the first sub block 143 from the storage controller 200 (S201). An erase command of the first sub block 143 may include a defect test execution command for the first sub block 143. The control logic 110 may control the first sub block 143 to perform a second test TEST2 in order to determine whether the first sub block 143 is defective (S202). Unlike the first test Test (TEST1 of FIG. 8), the second test TEST2 may be performed by changing a test condition. This will be described later.

The control logic 110 may determine whether the first sub block 143 is defective in accordance with the result of the second test TEST2 after the first sub block 143 performs the second test TEST2 (S203). When it is determined that the first sub block 143 is not defective (when it is determined that the block has been verified), the control logic 110 may control the first sub block 143 to perform an erase operation of the data written in the first sub block 143 (S204). When it is determined that the first sub block 143 is defective, the control logic 110 may transfer the data stored in the second sub block 144 included in the second block 142 to another block other than the second block 142 (S205). Although not shown, the second block 142 may be divided into three or more sub blocks. In this case, the data included in the second block 142 and stored in the plurality of sub blocks other than the first sub block 143, which is an object to be erased, may be transferred to another block (not shown) other than the second block 142. The control logic 110 may transfer the data stored in the second sub block 144 to another block (not shown) and then switch the second block 142 into a full block (S206).

When the second block 142 is switched into a full block, cell types of the plurality of memory cells included in each block may be equally switched. For example, when the cell type of the second block 142 is a single level cell (SLC), the cell type of the switched full block 145 may be also the SLC. When the cell type of the second block 142 is a multi-level cell (MLC), the cell type of the switched full block 145 may be also the MLC. When the control logic 110 receives an erase command from the storage controller 200 with respect to the switched block 145, the full block may be erased as described with reference to FIGS. 7 and 8.

The control logic 110 may receive the erase command of the block 145 switched from the storage controller 200 (S207). The erase command of the switched block 145 may include a defect test execution command for the switched block 145. The control logic 110 may control the switched block 145 to perform a first test TEST1 to determine whether the switched block 145 is defective (S208). The control logic 110 may determine whether the switched block 145 is defective in accordance with the result of the first test TEST1 after the switched block 145 performs the first test TEST1 (S209). When it is determined that the switched block 145 is not defective (when it is determined that the block has been verified), the control logic 110 may control the switched block 145 to perform an erase operation of the data written in the switched block 145 (S210). When it is determined that the switched block 145 is defective, the control logic 110 may switch the switched block 145 into a run-time bad block (RTBB) (S211).

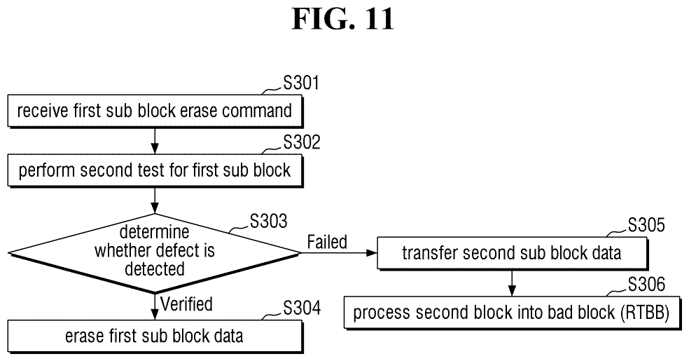

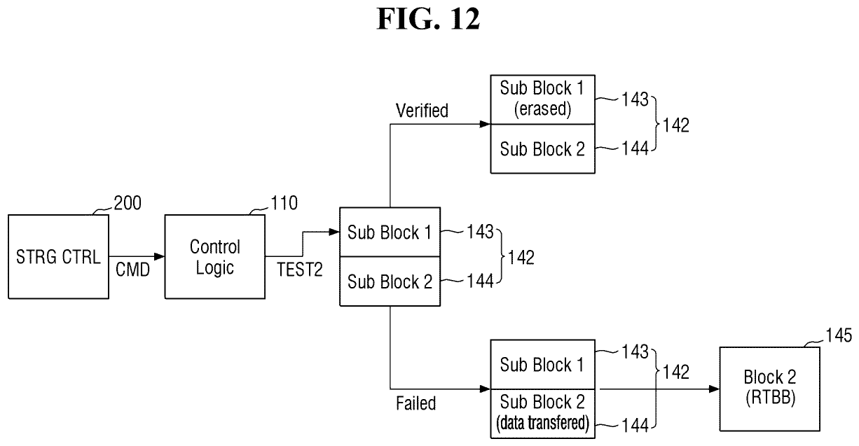

FIG. 11 is an exemplary flow chart illustrating an erase process of a sub block. FIG. 12 is an exemplary block diagram illustrating an erase process of a sub block.

Referring to FIGS. 11 and 12, unlike the first block (141 of FIG. 8), the second block 142 may be divided into a plurality of sub blocks. The second block 142 may include a first sub block 143 and a second sub block 144. In FIG. 12, the second block 142 is divided into two sub blocks, but this is only exemplary.

The control logic 110 may receive an erase command of the first sub block 143 from the storage controller 200 (S301). The erase command of the first sub block 143 may include a defect test execution command for the first sub block 143. The control logic 110 may control the first sub block 143 to perform a second test TEST2 in order to determine whether the first sub block 143 is defective (S302). Unlike the first test (TEST1 of FIG. 8), the second test TEST2 may be performed by changing a test condition. This will be described later. The control logic 110 may determine whether the first sub block 143 is defective in accordance with the result of the second test TEST2 after the first sub block 143 performs the second test TEST2 (S303). When it is determined that the first sub block 143 is not defective (when it is determined that the block has been verified), the control logic 110 may control the second sub block 144 to perform an erase operation of the data written in the first sub block 143 (S304). When it is determined that the first sub block 143 is defective, the control logic 110 may transfer the data stored in the second sub block 144 included in the second block 142 to another block other than the second block 142 (S305). Although not shown, the second block 142 may be divided into three or more sub blocks. In this case, the data included in the second block 142 and stored in the plurality of sub blocks other than the first sub block 143, which is an object to be erased, may be transferred to another block (not shown) other than the second block 142. The control logic 110 may transfer the data stored in the second sub block 144 to another block (not shown) and then switch the second block 142 into a run-time bad block (RTBB) (S306), unlike the description of FIGS. 9 and 10.

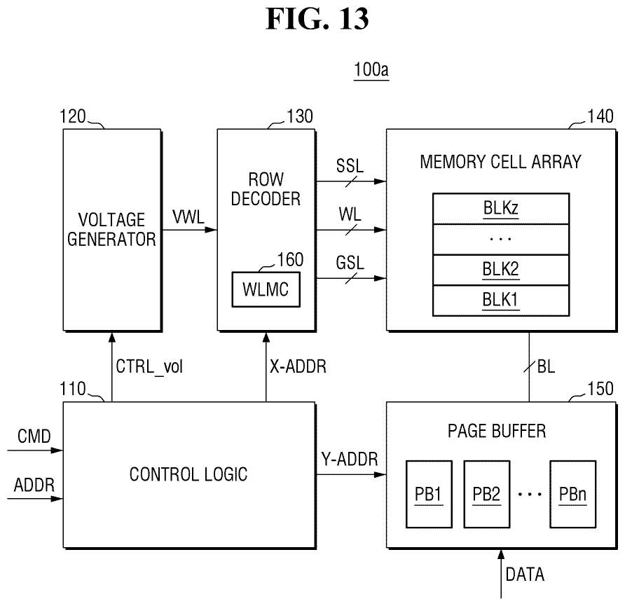

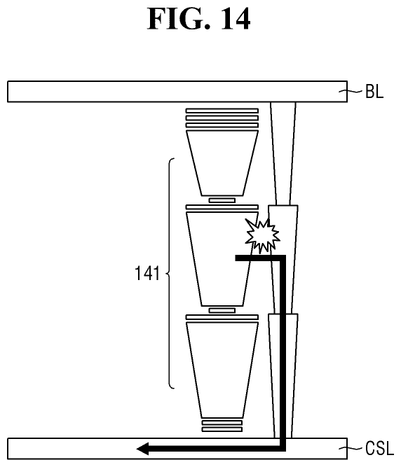

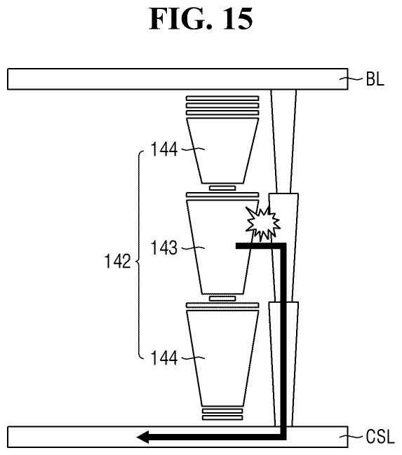

FIG. 13 is an exemplary block diagram illustrating a nonvolatile memory device according to some embodiments. FIG. 14 is an exemplary view illustrating a defect test process of a full block. FIG. 15 is an exemplary view illustrating a defect test process of a sub block.

Referring to FIGS. 13 to 15, a nonvolatile memory device 100a may further include a wordline leakage monitoring circuit (WLMC) 160. The wordline leakage monitoring circuit 160 is shown as being positioned inside the row decoder 130, but is not limited thereto, and may be positioned outside the row decoder 130. The wordline leakage monitoring circuit 160 may be connected to the plurality of wordlines included in the memory cell array 140.

A first test may be initiated to detect a defect of the first block 141 in response to the erase command of the first block 141 that is a full block. The first test may be performed in a first manner described below. In response to the first test, the row decoder 130 may select the plurality of wordlines connected to the plurality of memory cells included in the first block 141. In response to the first test, the voltage generator 120 may apply a preset voltage to the plurality of wordlines connected to the plurality of memory cells included in the first block 141 and float the preset voltage. For example, the voltage generator 120 may precharge and float a voltage equivalent to 4V to the plurality of wordlines connected to the plurality of memory cells included in the first block 141.

When a channel hole burst defect occurs in the first block 141, a wordline (hereinafter, referred to as a first defective wordline) adjacent to a place where the channel hole burst defect has occurred may be electrically short-circuited between channels. Since the plurality of precharged wordlines are in a floating state, a leakage current may flow from a first defective wordline to the common source line CSL of a ground (GND) state through a channel due to the channel hole burst defect. A voltage having the same level as the common source line CSL may be formed in the first defective wordline over time.

The wordline leakage monitoring circuit 160 may compare a voltage level applied to the plurality of wordlines included in the memory cell array 140 with a preset verification voltage level. The control logic 110 may determine whether the first block 141 is defective, based on the comparison result.

The second block 142 divided into sub blocks may include a first sub block 143 and a second sub block 144. A second test may be initiated to detect a defect of the first sub block 143 in response to an erase command of the first sub block 143. The second test may be performed in a first manner described below. In response to the second test, the row decoder 130 may select the plurality of wordlines connected to the plurality of memory cells included in the first sub block 143. In response to the second test, the voltage generator 120 may apply a preset voltage to the plurality of wordlines connected to the plurality of memory cells included in the first sub block 143 and float the preset voltage. For example, the voltage generator 120 may precharge and float a voltage equivalent to 4V to the plurality of wordlines connected to the plurality of memory cells included in the first sub block 143.

When a channel hole burst defect occurs in the first sub block 143, a wordline (hereinafter, referred to as a second defective wordline) adjacent to a place where the channel hole burst defect has occurred may be electrically short-circuited between channels. Since the plurality of precharged wordlines are in a floating state, a leakage current may flow from a second defective wordline to the common source line CSL of a ground (GND) state through a channel due to the channel hole burst defect. A voltage having the same level as the common source line CSL may be formed in the second defective wordline over time.

The wordline leakage monitoring circuit 160 may compare a voltage level applied to the plurality of wordlines included in the memory cell array 140 with a preset verification voltage level after a preset detection time elapses after floating. The control logic 110 may determine whether the first sub block 143 is defective, based on the comparison result.

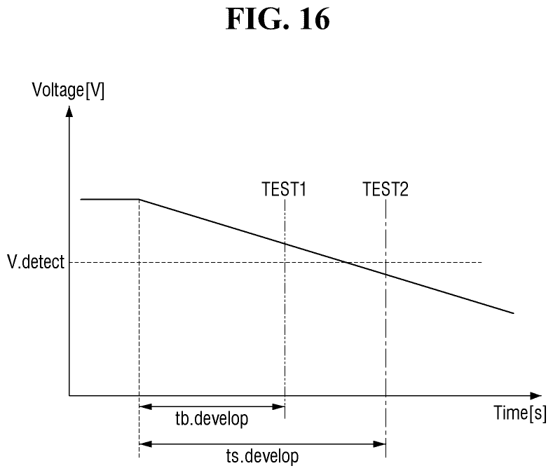

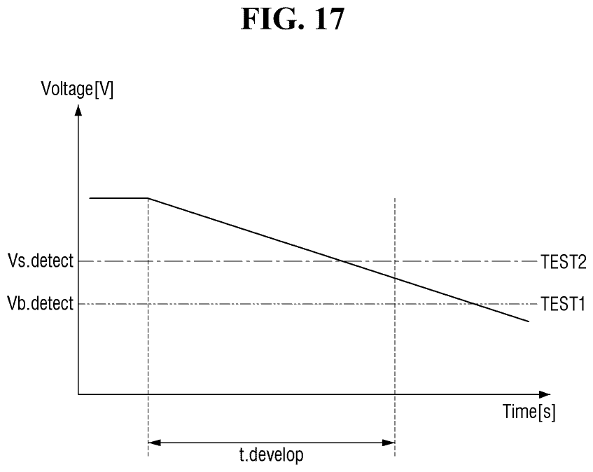

FIG. 16 is an exemplary graph illustrating comparison between conditions of a first test and a second test. FIG. 17 is an exemplary graph illustrating comparison between conditions of a first test and a second test. In the graphs illustrated in FIGS. 16 and 17, X-axis is a test progress time, and Y-axis is a voltage level.

According to some embodiments, both a first test for a full block and a second test for a sub block may be tests of a first type, but a criterion for defect determination may be different between the first test and the second test.

Referring to FIG. 16, the first test TEST1 and the second test TEST2 may be performed by varying a preset detection time. The first test TEST1 may compare a first verification voltage level V.detect with a voltage level of the selected wordlines after a first detection time tb.develop, and may determine a defect when the voltage level of at least a portion of the selected wordlines is lower than the first verification voltage level V.detect.

On the contrary, in the second test TEST2, a second detection time ts.develop may become a criterion. According to some embodiments, the first detection time tb.develop in the first test TEST1 may be shorter than the second detection time ts.develop in the second test TEST2. Depending on the degree of a channel hole burst defect, there may be a difference in speed at which a voltage level falls in a defective wordline. Since the second detection time ts.develop is longer than the first detection time tb.develop, the voltage level of the defective wordline may be more greatly reduced in the second test TEST2 than the first test TEST1 when there is no difference in the degree of the defect. In other words, since the second detection time ts.develop is longer than the first detection time tb.develop, a defect may be detected in the second test TEST2 even though no defect is detected in the first test TEST1. That is, the defect may be detected in the second test TEST2 at an early stage (i.e., more readily) as compared with the first test TEST1.

Referring to FIG. 17, the first test TEST1 and the second test TEST2 may be performed by varying a preset verification voltage level. The first test TEST1 may compare a second verification voltage level Vb.detect with a voltage level of the selected wordline after a third detection time t.develop, and may determine a defect when the voltage level of at least a portion of the selected wordline is lower than the second verification voltage level Vb.detect. In the second test TEST2, a third verification voltage level Vs.detect may become a criterion. According to some embodiments, the second verification voltage level Vb.detect in the first test TEST1 may be lower than the third verification voltage level Vs.detect in the second test TEST2. Depending on the degree of a channel hole burst defect, there may be a difference in speed at which a voltage level falls in a defective wordline. Since the third verification voltage level Vs.detect is higher than the second verification voltage level Vb.detect, a defect may be detected in the second test TEST2 even though no defect is detected in the first test TEST1. That is, a defect may be detected in the second test TEST2 at an early stage (i.e., more readily) as compared with the first test TEST1.

According to some embodiments, a channel hole burst defect of a sub block to be erased is more readily detected, and valid data stored in a sister sub block is transferred to another block, whereby the valid data stored in the sister sub block may be protected from the channel hole burst defect. Therefore, it is possible to provide a nonvolatile memory device and a storage device, in which reliability is increased.

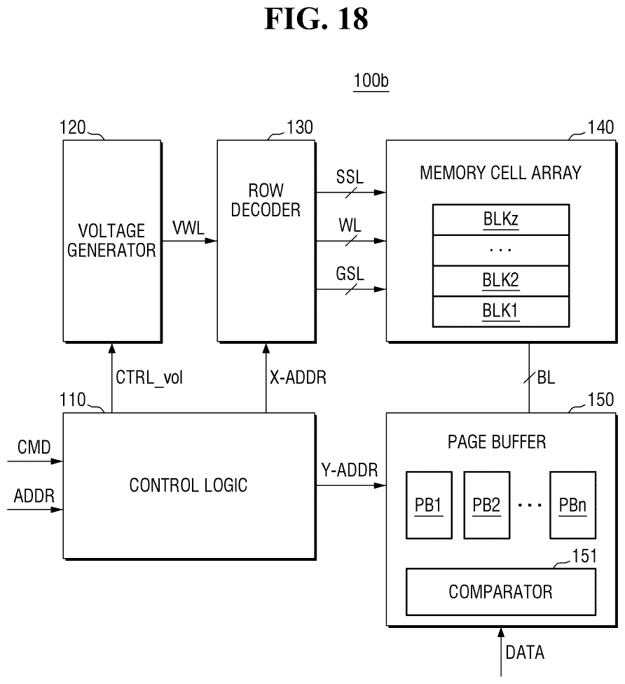

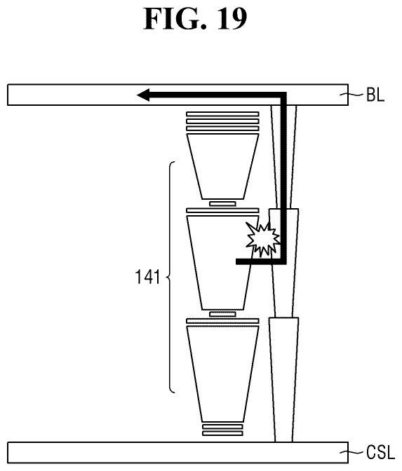

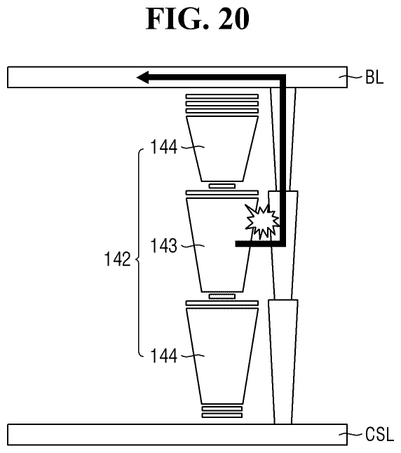

FIG. 18 is an exemplary block diagram illustrating a nonvolatile memory device according to some embodiments. FIG. 19 is an exemplary view illustrating a defect test process of a full block. FIG. 20 is an exemplary view illustrating a defect test process of a sub block. Referring to FIGS. 18 to 20, the page buffer 150 may further include a comparator 151.

A first test may be initiated to detect a defect of the first block 141 in response to an erase command of the first block 141 that is a full block. The first test may be performed in a second manner described below. In response to the first test, the row decoder 130 may select the plurality of wordlines connected to the plurality of memory cells included in the first block 141. In response to the first test, the voltage generator 120 may apply a preset voltage to the plurality of wordlines connected to the plurality of memory cells included in the first block 141. For example, the voltage generator 120 may precharge a voltage equivalent to 4V to the plurality of wordlines connected to the plurality of memory cells included in the first block 141. For example, the page buffer 150 may set the voltage level of the bitline BL connected to the first block 141 to 0V.

When a channel hole burst defect occurs in the first block 141, a wordline (hereinafter, referred to as a third defective wordline) adjacent to a place where the channel hole burst defect has occurred may be electrically short-circuited between channels. A leakage current may flow from the third defective wordline to the bitline BL set to 0V due to the channel hole burst defect. A voltage level of 0V or more may be formed in the bitline BL over time due to the third defective wordline.

The comparator 151 may compare a voltage level formed in the bitline BL connected to the first block 141 with a preset verification voltage level. The control logic 110 may determine whether the first sub block 143 is defective, based on the comparison result.

The second block 142 divided into sub blocks may include a first sub block 143 and a second sub block 144. A second test may be initiated to detect a defect of the first sub block 143 in response to an erase command of the first sub block 143. The second test may be performed in a second manner described below. In response to the second test, the row decoder 130 may select the plurality of wordlines connected to the plurality of memory cells included in the first sub block 143. In response to the second test, the voltage generator 120 may apply a preset voltage to the plurality of wordlines connected to the plurality of memory cells included in the first sub block 143. For example, the voltage generator 120 may precharge a voltage equivalent to 4V to the plurality of wordlines connected to the plurality of memory cells included in the first sub block 143. For example, the page buffer 150 may set the voltage level of the bitline BL connected to the first sub block 143 to 0V.

When a channel hole burst defect occurs in the first sub block 143, a wordline (hereinafter, referred to as a fourth defective wordline) adjacent to a place where the channel hole burst defect has occurred may be electrically short-circuited between channels. A leakage current may flow from the fourth defective wordline to the bitline BL set to 0V due to the channel hole burst defect. A voltage level of 0V or more may be formed in the bitline BL over time due to the fourth defective wordline.

The comparator 151 may compare a voltage level formed in the bitline BL connected to the first sub block 143 with a preset verification voltage level. The control logic 110 may determine whether the first sub block 143 is defective, based on the comparison result.

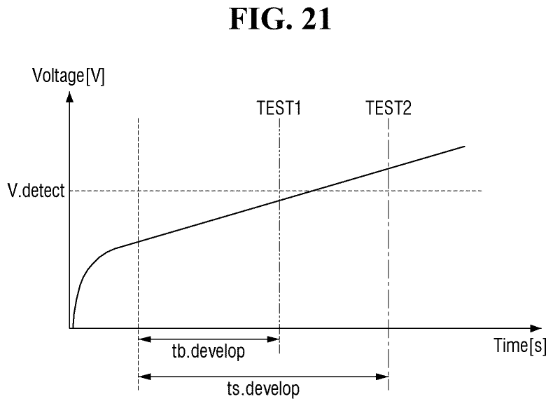

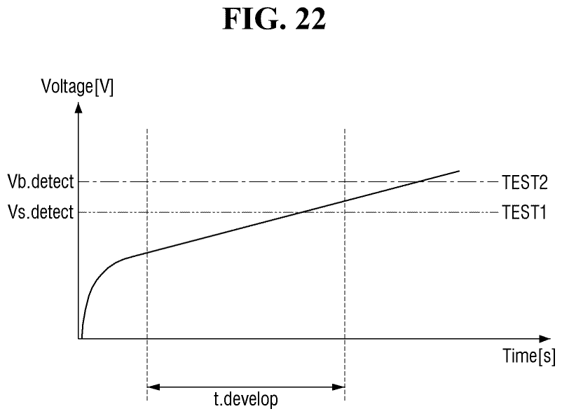

FIG. 21 is an exemplary graph illustrating comparison between conditions of a first test and a second test. FIG. 22 is an exemplary graph illustrating comparison between conditions of a first test and a second test. In the graphs illustrated in FIGS. 21 and 22, X-axis is a test progress time, and Y-axis is a voltage level.

According to some embodiments, both a first test for a full block and a second test for a sub block may be tests of a second type different from the first type of FIGS. 16 and 17, but a criterion for defect determination may be different between the first test and the second test. Referring to FIG. 21, the first test TEST1 and the second test TEST2 may be performed by varying a preset detection time. The first test TEST1 may compare a fourth verification voltage level V.detect with a voltage level of the bitline BL connected to the first block 141 after a fourth detection time tb.develop, and may determine a defect when the voltage level of the bitline BL connected to the first block 141 is higher than the fourth verification voltage level V.detect. In the second test TEST2, a fifth detection time ts.develop may become a criterion. According to some embodiments, the fourth detection time tb.develop in the first test TEST1 may be shorter than the fifth detection time ts.develop in the second test TEST2. Depending on the degree of a channel hole burst defect, there may be a difference in speed at which the voltage level of the bitline BL connected to the first block 141 is increased. Since the fifth detection time ts.develop is longer than the fourth detection time tb.develop, the voltage level of the bitline BL connected to the first block 141 may be more greatly increased in the second test TEST2 than the first test TEST1. In other words, since the fifth detection time ts.develop is longer than the fourth detection time tb.develop, a defect may be detected in the second test TEST2 even though no defect is detected in the first test TEST1. That is, the defect may be detected in the second test TEST2 at an early stage (i.e., more readily) as compared with the first test TEST1.

Referring to FIG. 22, the first test TEST1 and the second test TEST2 may be performed by varying a preset verification voltage level. The first test TEST1 may compare a fifth verification voltage level Vb.detect with a voltage level of the bitline BL connected to the first block 141 after a sixth detection time t.develop, and may determine a defect when the voltage level of the bitline BL connected to the first block 141 is lower than the fifth verification voltage level Vb.detect. In the second test TEST2, a sixth verification voltage level Vs.detect may become a criterion. According to some embodiments, the fifth verification voltage level Vb.detect in the first test TEST1 may be higher than the sixth verification voltage level Vs.detect in the second test TEST2. Depending on the degree of a channel hole burst defect, there may be a difference in speed at which the voltage level of the bitline BL connected to the first block 141 is increased. Since the sixth verification voltage level Vs.detect is lower than the fifth verification voltage level Vb.detect, a defect may be detected in the second test TEST2 even though no defect is detected in the first test TEST1. That is, the defect may be detected in the second test TEST2 at an early stage (i.e., more readily) as compared with the first test TEST1.

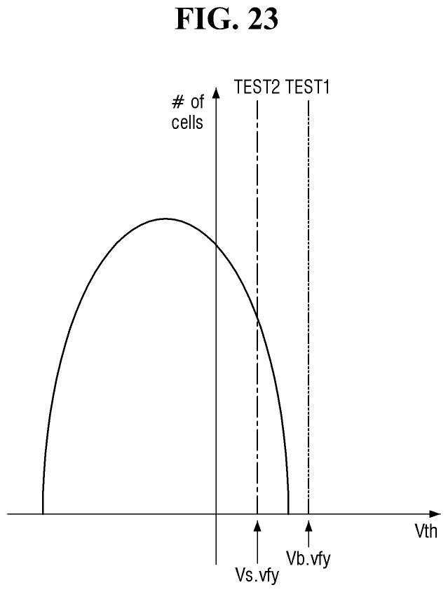

FIG. 23 is an exemplary dispersion graph illustrating comparison between conditions of a first test and a second test. In the dispersion graph shown in FIG. 23, X-axis is a threshold voltage Vth of memory cells included in a block for which a test is performed, and Y-axis is the number of memory cells included in a block for which a test is performed.

Referring to FIGS. 2, 3 and 23, a first test TEST1 may be initiated to detect a defect of the first block 141 in response to an erase command of the first block 141 that is a full block. The first test TEST1 may be performed in a third manner described below, which is different from the above-described first and second manners. In response to the first test TEST1, the row decoder 130 may select the plurality of wordlines connected to the plurality of memory cells included in the first block 141. In response to the first test, the control logic 110 may perform an erase operation for the first block 141. A threshold voltage level Vth of the memory cell for which the erase operation is performed may be lowered. The control logic 110 may determine whether the first block 141 is defective by comparing the threshold voltage level Vth of the plurality of memory cells included in the first block with a seventh verification voltage level Vb.vfy.

The second block 142 divided into sub blocks may include a first sub block 143 and a second sub block 144. A second test TEST2 may be initiated to detect a defect of the first sub block 143 in response to an erase command of the first sub block 143. The second test TEST2 may be performed in the third manner described below, which is different from the above-described first and second manners. In response to the second test TEST2, the row decoder 130 may select the plurality of wordlines connected to the plurality of memory cells included in the first sub block 143. According to some embodiments, both the first test TEST1 for a full block and the second test TEST2 for a sub block may be tests of a third type, but a criterion for defect determination may be different between the first test TEST1 and the second test TEST2. The first test TEST1 and the second test TEST2 may be performed by varying a preset detection time. In response to the second test TEST2, the control logic 110 may perform an erase operation for the first sub block 143. A threshold voltage level Vth of the memory cell for which the erase operation is performed may be lowered. The control logic 110 may determine whether the first sub block 141 is defective by comparing the threshold voltage level Vth of the plurality of memory cells included in the first sub block 143 with an eighth verification voltage level Vb.vfy.

According to some embodiments, the seventh verification voltage level Vb.vfy in the first test TEST1 may be higher than the eighth verification voltage level Vs.vfy in the second test TEST2. Depending on the degree of a channel hole burst defect, there may be a difference in threshold voltage level Vth between the memory cells for which the erase operation is performed. Since the eighth verification voltage level Vs.vfy is lower than the seventh verification voltage level Vb.vfy, a defect may be detected in the second test TEST2 even though no defect is detected in the first test TEST1. That is, the defect may be detected in the second test TEST2 at an early stage (i.e., more readily) as compared with the first test TEST1.

Although embodiments of the present disclosure have been described with reference to the accompanying drawings, embodiments of the present disclosure are not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

1. A nonvolatile memory device comprising:
a memory cell array including a first block including a first sub block having a first plurality of memory cells and a second sub block having a second plurality of memory cells, and a second block including a third plurality of memory cells and being a full block that is not divided into sub blocks;
a control logic configured to write, read, and erase data to and from the memory cell array;
a voltage generator configured to generate voltage applied to the memory cell array;
a row decoder configured to select wordlines connected to the first plurality of memory cells, the second plurality of memory cells and the third plurality of memory cells; and
a page buffer configured to select and sense bitlines connected to the first plurality of memory cells, the second plurality of memory cells and the third plurality of memory cells,
wherein the control logic performs a first test to detect a defect of the second block in response to a first erase command for the second block, and performs a second test different from the first test to detect a defect of the first sub block in response to a second erase command for the first sub block.

2. The nonvolatile memory device of claim 1, further comprising a wordline leakage monitoring circuit,
wherein in response to the first test,
the row decoder selects wordlines connected to the second block,
the voltage generator precharges wordlines connected to the second block with a first precharging voltage, and
the wordline leakage monitoring circuit determines whether the second block is defective by comparing a voltage of wordlines connected to the second block with a first verification voltage after a first detection time has elapsed, wherein in response to the second test,
the row decoder selects wordlines connected to the first sub block,
the voltage generator precharges wordlines connected to the first sub block with the first precharging voltage, and
the wordline leakage monitoring circuit determines whether the first sub block is defective by comparing a voltage of wordlines connected to the first sub block with the first verification voltage after a second detection time has elapsed, and
wherein the second detection time is longer than the first detection time.

3. The nonvolatile memory device of claim 1, further comprising a wordline leakage monitoring circuit,
wherein in response to the first test,
the row decoder selects wordlines connected to the second block,
the voltage generator precharges wordlines connected to the second block with a first precharging voltage, and
the wordline leakage monitoring circuit determines whether the second block is defective by comparing voltage of wordlines connected to the second block with a first verification voltage after a first detection time has elapsed,
wherein in response to the second test,
the row decoder selects wordlines connected to the first sub block,
the voltage generator precharges wordlines connected to the first sub block with the first precharging voltage, and
the wordline leakage monitoring circuit determines whether the first sub block is defective by comparing voltage of wordlines connected to the first sub block with a second verification voltage after the first detection time has elapsed, and
wherein the second verification voltage is higher than the first verification voltage.

4. The nonvolatile memory device of claim 1,
wherein in response to the first test,
the page buffer determines whether the second block is defective by comparing the change amount of a voltage of bitlines connected to the second block with a first verification voltage after a first detection time has elapsed,
wherein in response to the second test,
the page buffer determines whether the first sub block is defective by comparing the variation of voltage of bitlines connected to the first sub block with the first verification voltage after a second detection time has elapsed, and
wherein the second detection time is longer than the first detection time.

5. The nonvolatile memory device of claim 1,
wherein in response to the first test,
the page buffer determines whether the second block is defective by comparing variation of voltage of bitlines connected to the second block with a first verification voltage after a first detection time has elapsed, wherein in response to the second test,
the page buffer determines whether the first sub block is defective by comparing variation of voltage of bitlines connected to the first sub block with a second verification voltage after the first detection time has elapsed, and wherein the second verification voltage is lower than the first verification voltage.

6. The nonvolatile memory device of claim 1,
wherein in response to the first test,
the control logic performs a first erase operation for the second block, and
the page buffer determines whether the second block is defective by comparing threshold voltage of the third plurality of memory cells with a first verification voltage after the first erase operation is performed, wherein in response to the second test,
the control logic performs a second erase operation for the first sub block, and
the page buffer determines whether the first sub block is defective by comparing threshold voltage of the first plurality of memory cells with a second verification voltage after the second erase operation is performed, and wherein the second verification voltage is lower than the first verification voltage.

7. The nonvolatile memory device of claim 1, wherein the memory cell array includes a fourth plurality of memory cells, and further includes a third block different from the first block, and
the control logic transfers data of the second sub block to the third block when a defect of the first sub block is detected based on the second test.

8. The nonvolatile memory device of claim 1, wherein the control logic switches the first block into a third block which is a full block which is not divided into sub blocks when a defect of the first sub block is detected based on the first test.

9. The nonvolatile memory device of claim 8, wherein the first block and the third block have the same cell type.

10. The nonvolatile memory device of claim 8, wherein the control logic performs the first test to detect a defect of the third block in response to a third erase command for the third block.

11. The nonvolatile memory device of claim 10, wherein the control logic switches the third block into a run-time bad block when the defect of the third block is detected based on the first test.

12. The nonvolatile memory device of claim 1, wherein the control logic switches the first block into a run-time bad block when a defect of the first sub block is detected.

13. A nonvolatile memory device comprising:
a memory cell array including a first block including a first sub block having a first plurality of memory cells and a second sub block having a second plurality of memory cells, and a second block including a third plurality of memory cells;
a control logic configured to write, read, and erase data to and from the memory cell array;
a voltage generator configured to generate voltage applied to the memory cell array;
a row decoder configured to select wordlines connected to the first plurality of memory cells, the second plurality of memory cells and the third plurality of memory cells; and
a page buffer configured to select and sense bitlines connected to the first plurality of memory cells, the second plurality of memory cells and the third plurality of memory cells,
wherein the control logic performs a first test to detect a defect of the first sub block in response to a first erase command for the first sub block, transfers data of the second sub block to the second block when the defect of the first sub block is detected, and switches the first block into a third block which is a full block which is not divided into sub blocks.

14. The nonvolatile memory device of claim 13, wherein the first block and the third block have the same cell type.

15. The nonvolatile memory device of claim 13, wherein the control logic performs a second test to detect a defect of the third block in response to a second erase command for the third block.

16. The nonvolatile memory device of claim 15, wherein the control logic switches the third block into a run-time bad block when the defect of the third block is detected.

17. The nonvolatile memory device of claim 15, further comprising a wordline leakage monitoring circuit,
wherein in response to the first test,
the row decoder selects wordlines connected to the first sub block,
the voltage generator precharges wordlines connected to the first sub block with a first precharging voltage, and
the wordline leakage monitoring circuit determines whether the first sub block is defective by comparing voltage of wordlines connected to the first sub block with a first verification voltage after a first detection time has elapsed, wherein in response to the second test,
the row decoder selects wordlines connected to the third block,
the voltage generator precharges wordlines connected to the third block with the first precharging voltage, and
the wordline leakage monitoring circuit determines whether the third block is defective by comparing voltage of wordlines connected to the third block with the first verification voltage after a second detection time has elapsed, and
wherein the first detection time is longer than the second detection time.

18. The nonvolatile memory device of claim 15, further comprising a wordline leakage monitoring circuit,
wherein in response to the first test,
the row decoder selects wordlines connected to the first sub block,
the voltage generator precharges wordlines connected to the first sub block with a first precharging voltage, and
the wordline leakage monitoring circuit determines whether the first sub block is defective by comparing voltage of wordlines connected to the first sub block with a first verification voltage after a first detection time has elapsed,
wherein in response to the second test,
the row decoder selects wordlines connected to the third block,
the voltage generator precharges wordlines connected to the third block with the first precharging voltage, and
the wordline leakage monitoring circuit determines whether the third block is defective by comparing voltage of wordlines connected to the third block with a second verification voltage after the first detection time has elapsed, and
wherein the first verification voltage is higher than the second verification voltage.

19. The nonvolatile memory device of claim 15,
wherein in response to the first test,
the page buffer determines whether the first sub block is defective by comparing variation of voltage of bitlines connected to the first sub block with a first verification voltage after a first detection time has elapsed,
wherein in response to the second test,
the page buffer determines whether the third block is defective by comparing variation of voltage of bitlines connected to the third block with the first verification voltage after a second detection time has elapsed, and
wherein the first detection time is longer than the second detection time.

20-21. (canceled)

22. A storage device comprising:
a nonvolatile memory device; and
a storage controller controlling an operation of the nonvolatile memory device,
wherein the nonvolatile memory device includes:
a memory cell array including a first block including a first sub block including a first plurality of memory cells and a second sub block including a second plurality of memory cells, and a second block including a third plurality of memory cells and being a full block that is not divided into sub blocks;
a control logic configured to write, read, and erase data to and from the memory cell array by receiving a command of the storage controller;
a voltage generator configured to generate voltage applied to the memory cell array;
a row decoder configured to select wordlines connected to the first plurality of memory cells, the second plurality of memory cells and the third plurality of memory cells; and
a page buffer configured to select and sense bitlines connected to the first plurality of memory cells, the second plurality of memory cells and the third plurality of memory cells, and
wherein the storage controller controls the control logic to perform a first test for detecting a defect of the first sub block in order to erase data of the first sub block, and controls the control logic to perform a second test, which detects a defect of the second block and is different from the first test, in order to erase data of the second block.
